(19) United States
(12) Patent Application Publication
(10) Pub. No.: US 2023/0187267 A1
(43) Pub. Date: Jun. 15, 2023

(54) SEMICONDUCTOR DEVICE AND METHOD FOR MANUFACTURING SAME

(71) Applicant: DB HiTek Co., Ltd., Bucheon-si (KR)

(72) Inventors: Sang Il HWANG, Wonju-si (KR); Dae Il KIM, Cheongju-si (KR); Sung Hoon LEE, Cheongju-si (KR); Min Woo KIM, Incheon (KR); Young Joon CHOI, Ansan-si (KR)

(21) Appl. No.: 18/055,604

(22) Filed: Nov. 15, 2022

(30) Foreign Application Priority Data
Dec. 15, 2021 (KR) 10-2021-0179470

(51) Int. Cl. H01L 21/764; H01L 29/06

(52) U.S. Cl. CPC H01L 21/764; H01L 29/0649

(57) ABSTRACT

Provided is a semiconductor device and a method of manufacturing the same and, more particularly, to a semiconductor device and a method of manufacturing the same, seeking to reduce or prevent transmission of noise between adjacent devices and improve isolation characteristics by forming a second isolation region into an upper region (e.g., a pre-DTI region) and a lower region (e.g., a DTI region) relatively deep in the substrate.

### CROSS REFERENCE TO RELATED APPLICATION

The present application claims priority to Korean Patent Application No. 10-2021-0179470, filed Dec. 15, 2021, the entire contents of which are incorporated herein for all purposes by this reference.

### BACKGROUND OF THE INVENTION

### Field of the Invention

The present disclosure relates to a semiconductor device and a method of manufacturing the same and, more particularly, to a semiconductor device and a method of manufacturing the same, seeking to reduce or prevent transmission of noise between adjacent devices and improve isolation characteristics by including a second isolation region having an upper region (e.g., a pre-deep trench isolation [DTI] region) and a lower region (e.g., a DTI region) relatively deep in the substrate.

### Description of the Related Art

In recent bipolar-CMOS-DMOS (BCD) integrated circuit device manufacturing processes, a breakdown voltage of 100 V or more for at least the DMOS transistors is desirable, and a deep trench isolation (DTI) region helps to provide this high breakdown voltage and prevent an increase in leakage current by electrically isolating adjacent transistor devices.

FIG. 1 is a cross-sectional view for reference showing a DTI region in a conventional semiconductor device.

Referring to FIG. 1, a DTI region 910 used for electrical isolation between adjacent devices includes a trench region, formed by etching a substrate 901 to a predetermined depth in a single etching process, then filling the resulting trench with an insulating material. When the DTI region 910 is formed by a single etching process as described above, there may be technical limitations in forming the deep trench. That is, when the DTI region is formed by etching the substrate 901 in a single process, it is not easy to form the trench sufficiently deep to electrically isolate the adjacent devices. In addition, problems may occur during the process of filling the trench with the insulating material.

Due to such limitations, when the device is specified to achieve a breakdown voltage (BV) of 100V or more, the DTI region 910 may not be sufficiently deep, and thus the breakdown voltage characteristics may deteriorate because of an increase in the electric field area to the region of the substrate 901 below the DTI region 910 and an increase in the leakage current. Accordingly, as the separation distance between transistor devices on and/or in the substrate 901 increases in order to reduce or prevent transmission of noise between the adjacent devices, the overall chip size inevitably increases.

To solve the above-mentioned problems, the present disclosure concerns a novel semiconductor device having an improved structure and a method of manufacturing the same, described below.

### Document of Related Art

Korean Patent Application Publication No. 10-2003-0000592, entitled “METHOD OF MANUFACTURING SEMICONDUCTOR DEVICE WITH STI/DTI STRUCTURE.”

### SUMMARY OF THE INVENTION

The present disclosure has been made to solve the problems of the related art, and an objective of the present disclosure is to provide a semiconductor device and a method of manufacturing the same that improve isolation characteristics between adjacent devices, thereby improving device characteristics and reducing chip size by extending a second isolation region to relatively deep in a substrate by separately forming a first trench having a first, relatively large width (e.g., a “pre-DTI region”) and a second, relatively narrow trench (i.e., the DTI region). The second trench may overlap completely with the first trench.

Moreover, an objective of the present disclosure is to provide a semiconductor device and a method of manufacturing the same that prevent deterioration of characteristics of a second isolation region in advance by covering the second isolation region with an additional insulating layer to prevent a contact material such as tungsten from remaining on the second isolation region during a subsequent contact formation process.

Furthermore, an objective of the present disclosure is to provide a semiconductor device and a method of manufacturing the same that facilitate subsequent processing by removing a step height at the boundary between an interlayer dielectric and the second isolation region by performing a CMP process after removing an etch stop layer and depositing an additional insulating layer on the interlayer dielectric.

According to one or more embodiments of the present disclosure, there is provided a semiconductor device including a substrate; a gate electrode on or over the substrate; an interlayer dielectric covering the gate electrode and/or on the substrate; a first shallow trench isolation region in the substrate; a second isolation region overlapping at least partially with the first shallow trench isolation region and penetrating into the substrate; and an air gap in the second isolation region.

According to one or more other embodiments of the present disclosure, in the semiconductor device of the present disclosure, the second isolation region may include an upper region (which may be a “pre-DTI” region) overlapping with the first shallow trench isolation region; and a lower region (which may be a DTI region) connected to the upper region, extending a predetermined distance (e.g., into the substrate), and having a width smaller than that of the upper region.

According to one or more other or further embodiments of the present disclosure, in the semiconductor device of the present disclosure, the upper region may have a smaller width than that of the first shallow trench isolation region.

According to one or more other or further embodiments of the present disclosure, in the semiconductor device of the present disclosure, the air gap may be (i) in and/or (ii) adj acent to a lowermost surface of the lower region and/or under the upper region.

According to one or more other or further embodiments of the present disclosure, in the semiconductor device of the present disclosure, the upper region may be adjacent to the interlayer dielectric.

According to one or more other or further embodiments of the present disclosure, a semiconductor device of the present disclosure may include a substrate; a first buried layer having a second conductivity type in the substrate; a deep well region directly or indirectly connected to the buried layer having the second conductivity type; a first well region in the deep well region; a drain in the first well region and at a surface of the substrate; a body region having a first conductivity type in the substrate; a source in the body region and at the surface of the substrate; a gate electrode on or over the substrate; an interlayer dielectric covering the gate electrode and/or on the substrate; a first shallow trench isolation region in the substrate; a second isolation region penetrating the first shallow trench isolation region and the substrate; and an air gap in the second isolation region.

According to one or more other or further embodiments of the present disclosure, the semiconductor device of the present disclosure may further include a high-voltage well region having the second conductivity type, connected to the first buried layer and the deep well region; and a second buried layer having the first conductivity type in the substrate.

According to one or more other or further embodiments of the present disclosure, in the semiconductor device of the present disclosure, the second isolation region may include an upper region (e.g., a “pre-DTI” region) overlapping with the first shallow trench isolation region; and a lower region (i.e., a DTI region) connected to the upper region, extending a predetermined distance (e.g., into the substrate), and having a width smaller than that of the upper region. The upper region may be covered by the interlayer dielectric.

According to one or more other or further embodiments of the present disclosure, the semiconductor device of the present disclosure may further include a dummy gate on the first shallow trench isolation region (and/or on the substrate).

According to one or more other or further embodiments of the present disclosure, in the semiconductor device of the present disclosure, the upper region may penetrate or pass through the dummy gate, and have sides in contact with and/or surrounded by the interlayer dielectric.

According to one or more embodiments of the present disclosure, there is provided a method of manufacturing a semiconductor device. The method includes forming a first shallow trench isolation region in a substrate; forming a gate electrode on or over the substrate; forming an interlayer dielectric covering the gate electrode and/or on the substrate; forming an upper isolation region (e.g., the upper region of a second isolation region) that overlaps the first shallow trench isolation region and penetrates the interlayer dielectric; and forming a lower isolation region (e.g., the lower region of the second isolation region) in the substrate, the lower isolation region having a smaller width than that of the upper isolation region (and optionally is under the upper isolation region).

According to one or more other or further embodiments of the present disclosure, in the method of manufacturing a semiconductor device of the present disclosure, the lower isolation region may include an air gap therein.

According to one or more other or further embodiments of the present disclosure, in the method of manufacturing a semiconductor device of the present disclosure, forming the upper isolation region may include forming a first trench by etching the interlayer dielectric (e.g., above the first shallow trench isolation region) and the first shallow trench isolation region; and depositing an insulating layer in the first trench, and forming the lower isolation region may include forming a second trench by etching the substrate under the first shallow trench isolation region (e.g., after forming the first trench); and depositing the insulating layer in the second trench.

According to one or more other or further embodiments of the present disclosure, in the method of manufacturing a semiconductor device of the present disclosure, the insulating layer in the upper isolation region and in the lower isolation region may be deposited practically simultaneously (i.e., in a single and/or uninterrupted deposition step or process), and depositing the insulating layer may include depositing a first insulating layer on the interlayer dielectric and on sidewalls of the first trench, etching the first insulating layer (e.g., anisotropically, to leave an insulating spacer or liner on sidewalls of the first trench and the interlayer dielectric); and depositing a second insulating layer on the insulating spacer or liner in the first trench and the second trench. In such embodiment(s), the first insulating layer may be further deposited on sidewalls of the second trench.

According to one or more other or further embodiments of the present disclosure, the method of manufacturing a semiconductor device of the present disclosure may further include forming a dummy gate on the first shallow trench isolation region and/or the substrate, and the upper isolation region may penetrate or pass through the dummy gate.

According to one or more other or further embodiments of the present disclosure, a method of manufacturing a semiconductor device of the present disclosure may include forming an STI region in a substrate; forming a gate electrode on or over the substrate; forming an interlayer dielectric covering the gate electrode and/or on the substrate; forming an etch stop layer on the interlayer dielectric; forming a first trench by etching the etch stop layer, the interlayer dielectric, and the STI region; forming a second trench having a smaller width than the first trench by etching the substrate under the first trench to a predetermined depth; filling the first trench and the second trench with a first insulating layer; removing the first insulating layer on the etch stop layer; and depositing a second insulating layer on the first insulating layer in the first trench and the second trench. The second insulating layer may have an air gap therein.

According to one or more other or further embodiments of the present disclosure, the method of manufacturing a semiconductor device of the present disclosure may further include removing the second insulating layer remaining on the etch stop layer; and etching the etch stop layer.

According to one or more other or further embodiments of the present disclosure, the method of manufacturing a semiconductor device of the present disclosure may further include depositing a third insulating layer on the second insulating layer and the interlayer dielectric (e.g., from which the etch stop layer has been removed); and planarizing the third insulating layer (e.g., by partially etching the third insulating layer).

According to one or more other or further embodiments of the present disclosure, in the method of manufacturing a semiconductor device of the present disclosure, forming the first trench may include forming a first photoresist pattern on the etch stop layer; and sequentially etching the etch stop layer, the interlayer dielectric, and the first shallow trench isolation region.

According to one or more other or further embodiments of the present disclosure, in the method of manufacturing a semiconductor device of the present disclosure, forming the second trench may include forming a second photoresist pattern on the etch stop layer and along sidewalls of the first trench; and etching the substrate under the first trench.

The above configurations may have one or more of the following effects.

The present disclosure can improve isolation characteristics between adjacent devices, thereby improving device characteristics and reducing chip size by allowing a second isolation region to easily extend to a deep region in a substrate by separately forming a first trench having a relatively shallow depth and a relatively large width and a second deeper, overlapping trench having a relatively narrow width.

Moreover, the present disclosure can prevent deterioration of characteristics of the second isolation region in advance by covering the second isolation region with an additional insulating layer to prevent a contact material such as tungsten from remaining on the second isolation region during a subsequent contact formation process.

Furthermore, the present disclosure can facilitate subsequent processing by removing a step height at the boundary between an interlayer dielectric and a second isolation region by performing a CMP process after removing an etch stop layer and depositing an additional insulating layer on the interlayer dielectric.

Meanwhile, it should be added that even if effects are not explicitly mentioned herein, the effects described in the following specification expected by the technical features of the present disclosure and their potential effects are treated as if they were described in the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view for reference showing a DTI region in a conventional semiconductor device;

FIG. 2 is a cross-sectional view of a semiconductor device according to one or more embodiments of the present disclosure;

FIG. 3 is a cross-sectional view showing a dummy gate in the semiconductor device illustrated in FIG. 2;

FIG. 4 is a reference view showing isolation characteristics according to the depth of a second isolation region (or a DTI region);

FIGS. 5 to 12 are cross-sectional views showing a method of manufacturing a semiconductor device according to one or more embodiments of the present disclosure; and

FIGS. 13 and 15 are cross-sectional views showing a process for removing the step height at the boundary between the second isolation region and the interlayer dielectric.

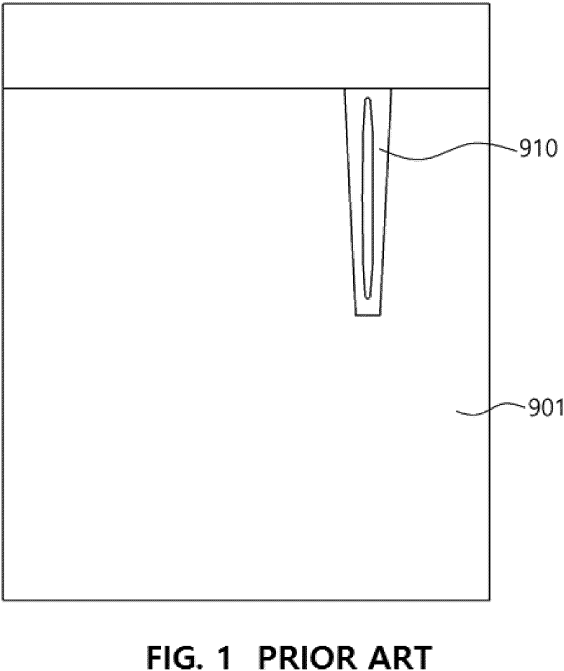

### DETAILED DESCRIPTION OF THE INVENTION

Hereinafter, embodiments of the present disclosure will be described in more detail with reference to the accompanying drawings. Embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those of ordinary skill in the art.

Hereinafter, it should be noted that when one component (or layer) is described as being on another component (or layer), the one component may be directly on another component, or one or more further component(s) or layer(s) may be located between the one component and the other component. In addition, when one component is expressed as being directly on or above another component, no other component(s) are located between the one component and the other component. Moreover, being located “on top”, “above”, “below”, “on”, “under” or “on one (first) side” or “on opposite sides” of a component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term a metal oxide semiconductor (MOS) used below is a general term, and “M” is not limited to only metal and may refer to various types of conductors. Also, “S” may be a substrate or a semiconductor structure, and “O” is not limited to oxide and may include various types of organic or inorganic insulating materials.

Moreover, the conductivity type of a doped region or component may be defined as “p-type” or “n-type” according to the main carrier characteristics, but this is only for convenience of description, and the technical spirit of the present disclosure is not limited to what is illustrated. For example, hereinafter, “p-type” or “n-type” may be replaced with the more general terms “first conductivity type” or “second conductivity type”, and here, the first conductivity type may refer to p-type, and the second conductivity type may refer to n-type.

Furthermore, it should be understood that “high concentration” and “low concentration” referring to the doping concentration of the impurity region mean the relative doping concentration of one component to one or more other components.

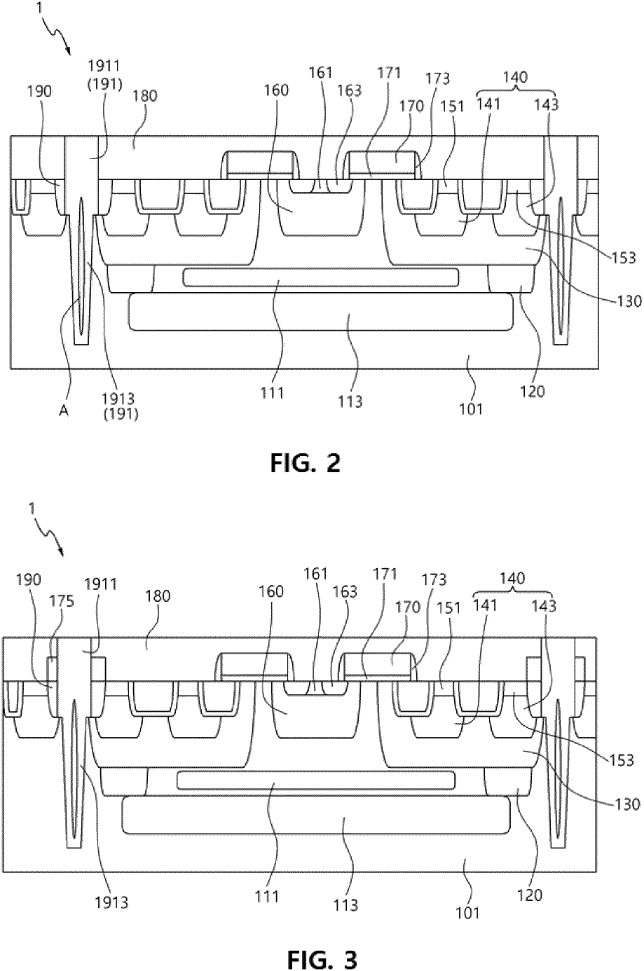

FIG. 2 is a cross-sectional view of a semiconductor device according to one or more embodiments of the present disclosure, and FIG. 3 is a cross-sectional view showing a dummy gate in the semiconductor device illustrated in FIG. 2.

Hereinafter, a semiconductor device 1 according to one or more embodiments of the present disclosure will be described in detail with reference to the accompanying drawings.

Referring to FIG. 2, the present disclosure relates to the semiconductor device 1 and, more particularly, to the semiconductor device 1 including a second isolation region having an upper region (e.g., a “pre-DTI” region) and a lower region (e.g., a DTI region) relatively deep in the substrate 101, thereby reducing or preventing transmission of noise between adjacent devices and improving isolation characteristics.

The depth of the second isolation region is preferably about 30 µm or more and 40 µm or less, for example, from the surface of the substrate 101. However, it should be noted that the scope of the present disclosure is not limited by the above example.

Hereinafter, the structure of the semiconductor device 1 according to embodiment(s) of the present disclosure will be described in detail.

First, a well region (not shown) used as an active region may be on or in the substrate 101, and this active region may be defined by a first shallow trench isolation region 190. The substrate 101 may comprise a single crystal silicon wafer doped with a first conductivity type dopant, a P-type diffusion region in such a wafer, or a P-type epitaxial layer on the wafer. The first isolation region 190 may be formed by shallow trench isolation (STI), but is not limited thereto.

A first buried layer 111 and a second buried layer 113 may be in the substrate 101. For example, the first buried layer 111 may be above the second buried layer 113. In addition, a high-voltage well region 120 may be connected to the second buried layer 113 at a side or edge thereof. The high-voltage well region 120 comprises an ion implantation region (HVNWELL) having a second conductivity type, and may be in the substrate 101 and on the second buried layer 113. The aforementioned first buried layer 111 may comprise an impurity doped region having a first conductivity type, and the second buried layer 113 may comprise an impurity doped region having a second conductivity type. It should be noted that the first buried layer 111 and the high-voltage well region 120 are not essential components of the present disclosure and may be omitted in some cases.

A deep well region 130 may be in the substrate 101 and on the high-voltage well region 120. The deep well region 130 is connected (e.g., at one side) to the high-voltage well region 120 and may comprise a second conductivity type impurity doped region (e.g., a deep n-type well DNWELL). The deep well region 130 may be directly connected to the second buried layer 113 in some cases.

In the deep well region 130, for example, first and second well regions 141 and 143 (together, well regions 140) having the second conductivity type are spaced apart (e.g., by an STI structure 190). A drain 151 may be in the first well region 141 and a heavily doped region 153 may be in the second well region 143. The drain 151 comprises an impurity having the second conductivity type and may contain a higher concentration of the impurity than the first well region 141. The heavily doped region 153 also comprises an impurity having the second conductivity type and may contain a higher concentration of the impurity than the second well region 143.

The drain 151 and the heavily doped region 153 are preferably on or at the surface of the substrate 101. The above-described heavily doped region 153 functions as a guard ring together with the second well region 143 to reduce leakage current and improve safe operating area (SOA) conditions (e.g., of the corresponding DMOS transistor). The drain 151 may be electrically connected to a drain electrode, and the well region 141 surrounding the drain 151 may comprise a drain extension region that may improve breakdown voltage characteristics of the corresponding high voltage (e.g., DMOS) semiconductor device.

Abody region 160 is in the substrate 101 between adjacent gates 170 of adjacent high voltage (e.g., DMOS) semiconductor devices. The body region 160 comprises a heavily doped region having the first conductivity type, and may be spaced apart from the deep well region 130 (e.g., by channels [or portions thereof] of the adjacent high voltage semiconductor devices). A source 163 is in the body region 160 and on or at the surface of the substrate 101. The source 163 comprises a heavily doped region having the first conductivity type and may be electrically connected to a source electrode. In addition, a body contact 161 may be in the body region 160 and adjacent to or in contact with the source 163. The body contact 161 may comprise a heavily doped region having the first conductivity type.

Agate electrode 170 is on or above the substrate 101. To be specific, the gate electrode 170 may be between the drain 151 and the source 163, within the active region. The gate electrode 170 is over a channel region of a corresponding high voltage semiconductor device, and the voltage applied to the gate electrode 170 controls the conductivity of the channel region. The gate electrode 170 may comprise, for example, conductive polysilicon, a metal, a conductive metal nitride, or a combination thereof, and may be formed by CVD, PVD, ALD, MOALD, or MOCVD, etc., but is not limited thereto.

Agate insulation film 171 is between the gate electrode 170 and the surface of the substrate 101, and the gate insulation film 171 may comprise a silicon oxide layer, a high-k insulator layer (e.g., HfO₂, hafnium silicate, ZrO₂, zirconium silicate, etc., which may or may not be nitrided), and a combination thereof. The gate insulation film 171 may be formed by ALD, CVD, or PVD.

One or more sidewalls of the gate electrode 170 may have a gate spacer 173 thereon or in contact therewith. The gate spacer 173 may comprise a nitride film (e.g., silicon nitride), an oxide film (e.g., silicon dioxide), or a combination thereof (e.g., silicon nitride on silicon dioxide).

In addition, a dummy gate 175 may be on the substrate 101, overlapping the first isolation region 190 (to be described later; see FIG. 3). The dummy gate 175 may comprise the same material as the gate electrode 170, and may also include a thin insulating layer between this material and the surface of the substrate 101. The upper region 1911 of the second isolation region 191 may penetrate or pass through the dummy gate 175 and the first isolation region 190.

In addition, on the substrate 101, an interlayer dielectric 180 may completely cover the gate electrode 170. The interlayer dielectric 180 may comprise, for example, a borophosphosilicate glass (BPSG) film, a silicon oxide film formed from tetraethyl orthosilicate (TEOS) or silane (SiH₄), a silicon nitride film, combinations thereof, etc., but the scope of the present disclosure is not limited thereto. The interlayer dielectric 180 may also surround and/or cover the upper part of the second isolation region 191. A detailed description thereof will be described later with regard to the method of manufacturing a semiconductor device.

The first isolation region 190 has a predetermined depth (e.g., from the surface of the substrate 101). The first isolation region 190 is an isolation layer defining the active region as described above, and may be formed, for example, by STI. In addition, the second isolation region 191 may overlap (e.g., be completely within the area of) the first isolation region 190. The second isolation region 191 includes a DTI structure, and it is preferable to overlap with the first isolation region 190 in order to maintain the area of the active region.

The second isolation region 191 may include an upper region 1911 (e.g., a pre-DTI region) and a lower region 1913 (i.e., a DTI region). The upper region 1911 penetrates, passes through or at least partially overlaps the interlayer dielectric 180, the first isolation region 190, and if present, the dummy gate 175. The upper region 1911 may have a lowermost surface (i) at a height substantially the same as or (ii) adjacent to a lowermost surface of the first isolation region 190.

Referring to FIGS. 2 and 3, the upper region 1911 may have a width that is smaller than the width of the first isolation region 190 or the dummy gate 175. The lower region 1913 is connected to the upper region 1911. The lower region 1913 may be narrower than the upper region 1911 and have inclined sidewalls, rather than vertically straight sidewalls. This is because the etching behavior of the substrate 101 with certain etchants (e.g., dry chemical and/or plasma-based etchants) may result in formation of sloped sidewalls in the trench. In contrast, the upper region 1911 may have a substantially uniform width along its entire depth, or may include a portion that is wider at or toward the bottom, but is not limited thereto. In addition, the lower region 1913 has a width smaller than that of the upper region 1911. It is preferable that both the upper region 1911 and the lower region 1913 be filled with the same material as or a similar material to the interlayer dielectric 180.

An air gap A is in the second isolation region 191. For example, the air gap A may be entirely in the lower region 1913, or may a first (e.g., upper) end of the air gap A may be in the upper region 1911. Preferably, the air gap A does not extend to an upper portion of the upper region 1911 (e.g., above the surface of the substrate 101). This prevents a metal material such as tungsten (W) from penetrating into the air gap A in a subsequent contact formation process.

There is a technical limitation in the trench depth when forming a DTI region in a single process, without dividing the second isolation region 191 into the upper region 1911 and the lower region 1913 as in the present disclosure. That is, when the DTI region is formed by etching the substrate 101 in a single process, it is not easy to form the DTI region sufficiently deep to completely isolate adjacent devices electrically. In particular, when the substrate 101 has a thickness sufficient to achieve a breakdown voltage (BV) of 100 V or more, the corresponding DTI region may not be sufficiently deep, which leads to deterioration of the breakdown voltage characteristics due to an increase in the electric field area to the region below the DTI region and an increase in the leakage current. In addition, in order to reduce or prevent transmission of noise between adj acent devices, the separation distance between adj acent devices increases, and thus the overall chip size inevitably increases.

In order to prevent the above-described problems, in the semiconductor device 1 according to one or more embodiments of the present disclosure, the second isolation region 191, particularly the lower region 1913, is sufficiently deep to electrically isolate adjacent devices, maintain breakdown voltage characteristics, and minimize device area by virtue of the lower region 1913 having a relatively narrow width (the DTI structure) and the upper region 1911 having a relatively large width (the “pre-DTI” structure). As previously described, it is preferable that the depth of the second isolation region 191 is approximately 30 µm or more and 40 µm or less from the surface of the substrate 101.

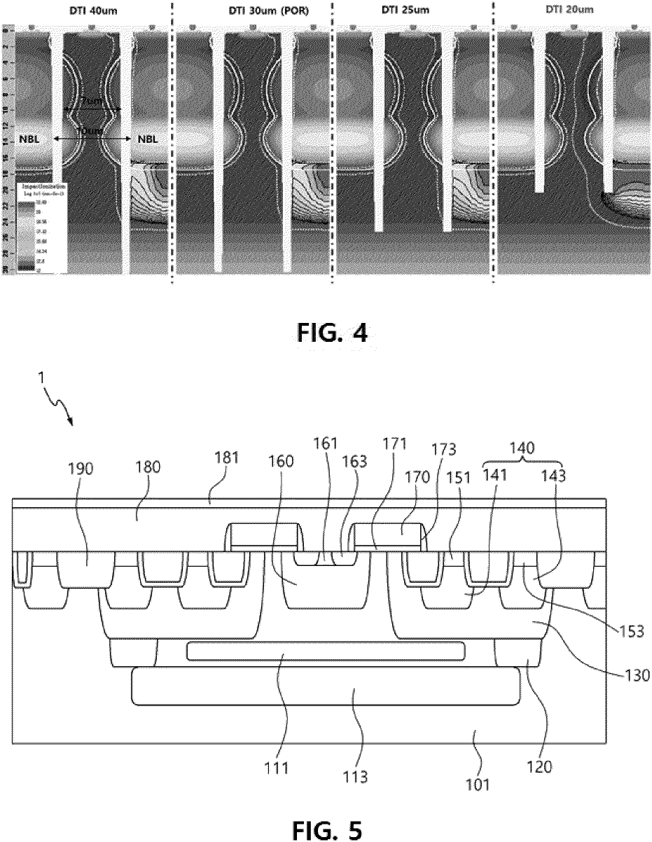

FIG. 4 is a reference view showing isolation characteristics according to the depth of the second isolation region (or the DTI structure).

As can be seen in FIG. 4, when a DTI structure has a depth of 20 to 25 µm in a high-voltage semiconductor device, the electric field below the DTI structure increases, whereas a DTI structure having a depth of 30 µm or more (as in the present disclosure) reduces or prevents an increase in the electric field (e.g., relative to the same device having a DTI structure with a depth of 40 µm), thereby improving isolation characteristics.

FIGS. 5 to 12 are cross-sectional views showing a method of manufacturing a semiconductor device according to one or more embodiments of the present disclosure.

Hereinafter, a method of manufacturing a semiconductor device according to one or more embodiments of the present disclosure will be described in detail with reference to the accompanying drawings. For convenience of description, descriptions of well regions, buried layers, the source and the drain in the substrate, and the gate electrode and the dummy gate on the substrate, will be omitted, while the processes before and after formation of the second isolation region 191 will be mainly described.

First, referring to FIG. 5, the interlayer dielectric 180 is blanket deposited on the gate electrode 170, the dummy gate 175 (if present), and exposed areas of the substrate 101. As previously described, the interlayer dielectric 180 may comprise, for example, a BPSG layer, a silicon (di)oxide layer, and/or a silicon nitride layer, but is not limited thereto. The interlayer dielectric 180 may be planarized by polishing (e.g., mechanical polishing or CMP). Then, an etch stop layer 181 is formed on the interlayer dielectric 180 by blanket deposition (e.g., PVD, CVD, etc.). The etch stop layer 181 may function as a CMP / etch stop layer for a subsequent CMP or etching process, and may comprise, for example, a SiN layer.

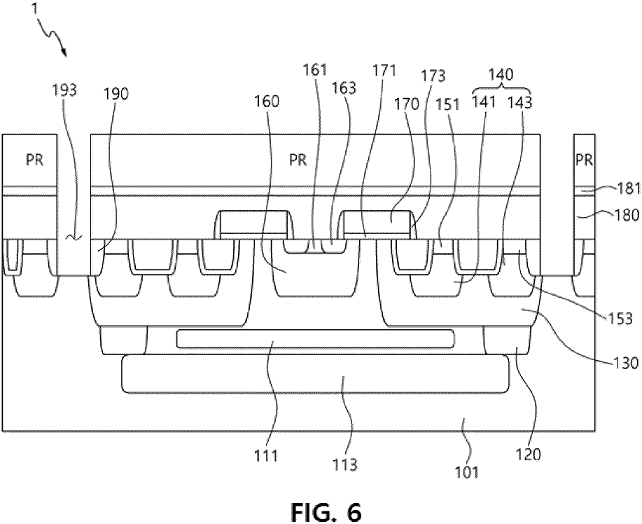

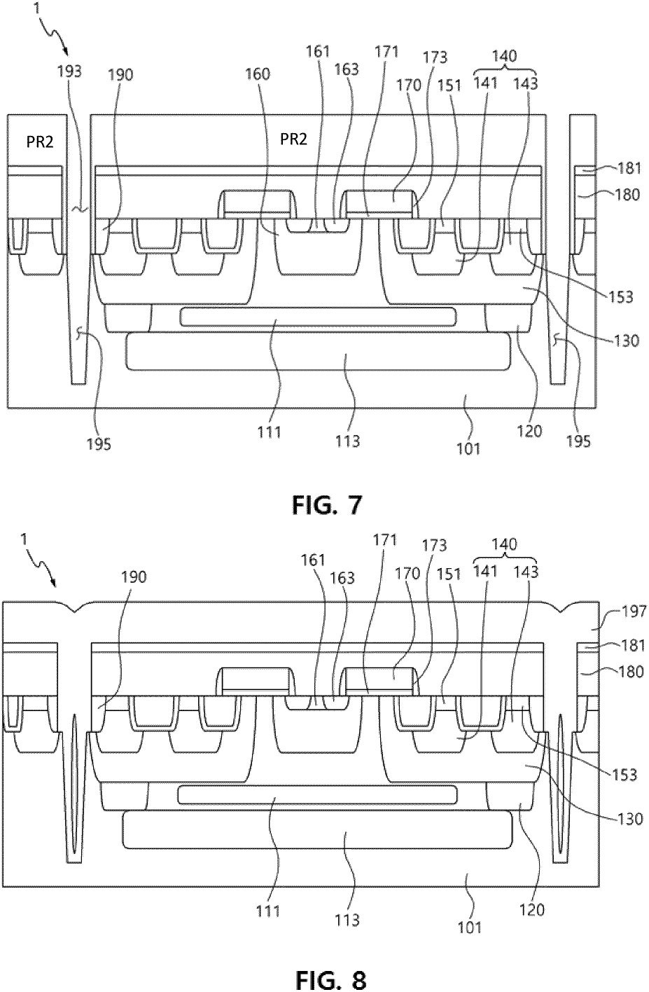

Thereafter, referring to FIG. 6, the etch stop layer 181, the interlayer dielectric 180, and the first shallow trench isolation layer 190 are etched to form a first trench 193 in which the upper region 1911 will be formed. The process of forming the first trench 193 will be described in detail. For example, a photoresist layer PR having an opening in the area in which the first trench 193 is to be formed is patterned on the etch stop layer 181. Then, the etch stop layer 181, the interlayer dielectric 180, and the first isolation layer 190 are sequentially etched to form the first trench 193.

After the first trench 193 is formed, the photoresist layer PR is removed. This may be done by photoresist stripping process and cleaning.

Thereafter, referring to FIG. 7, a second trench 195 is formed in which the lower region 1913 is to be formed. The second trench 195 may have a depth of 30 to 40 µm (e.g., from the surface of the substrate 101). The second trench 195 has a narrower horizontal width than that of the first trench 193, and the second trench 195 may have sidewalls that are inclined (e.g., a gradually narrower width as one progresses toward the bottom of the trench), or may have a substantially uniform width. The process of forming the second trench 195 will be described in detail. For example, a second photoresist layer PR2 is patterned on the etch stop layer 181 and along sidewalls of the first trench 193. That is, the patterned photoresist layer PR2 includes an opening substantially as wide as the uppermost part or edge of the second trench 195. Then, the surface of the substrate 101 under the first trench 193 is etched to a depth of about 30 to 40 µm.

After the second trench 195 is formed, the second photoresist film PR2 is removed (e.g., by stripping and cleaning).

Thereafter, referring to FIG. 8, an insulating layer 197 is deposited on the etch stop layer 181 and in the first trench 193 and the second trench 195. The insulating layer 197 may comprise a TEOS film, but the scope of the present disclosure is not limited thereto, and any silicon oxide film may be used. When performing this deposition process, the insulating layer 197 is deposited on the etch stop layer 181 and fills the first trench 193 and the second trench 195. An air gap (not numbered) may form in the insulating layer 197, at least in the second trench 195.

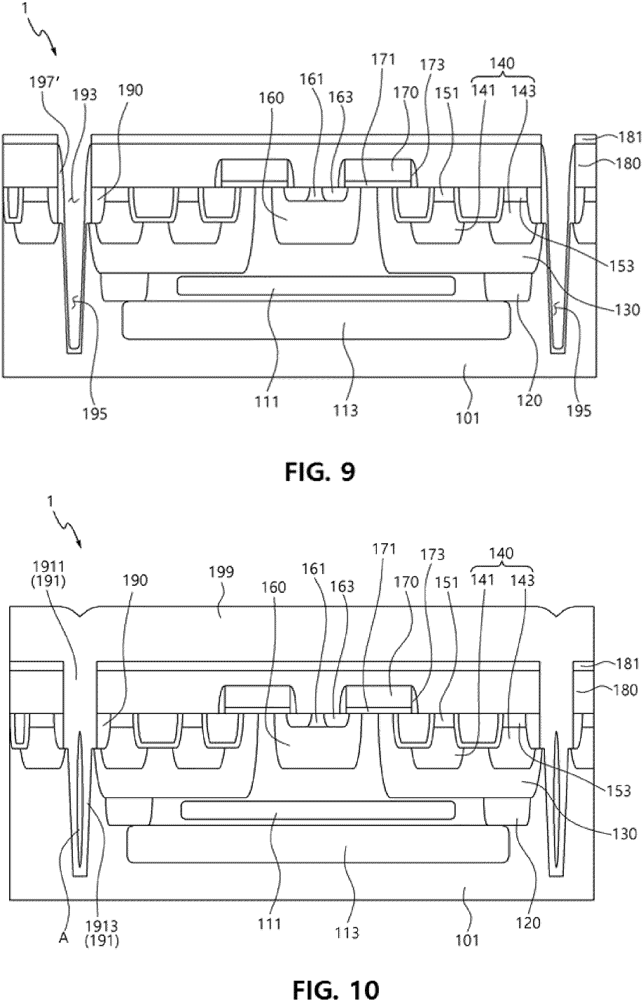

Thereafter, referring to FIG. 9, an etch-back process is performed on the deposited insulating layer 197. The etch-back process is a process that at least partially (and preferably completely) etches the insulating layer 197 on the etch stop layer 181 and partially etches the insulating layer 197 in the first trench 193 and the second trench 195, leaving an insulating spacer or liner 197′ in the first and second trenches 193 and 195. When the etching of the insulating layer 197 is completed, a cleaning process is performed. By these processes, the insulating spacer or liner 197′ may remain in the first trench 193 and the second trench 195, with a predetermined thickness along the wall of the second trench 195.

Thereafter, referring to FIG. 10, a second insulating layer 199 is deposited on the etch stop layer 181 and inside the first trench 193 and the second trench 195 along the insulating spacer or liner 197′. The above-described insulating layer 197 is referred to as a “first insulating layer” to distinguish it from the second insulating layer 199. By depositing the second insulating layer 199, the air gap A is formed in the first and second trenches 193 and 195 to reduce or prevent transmission of noise between adj acent devices, thereby making the devices electrically stable.

It is preferable that the air gap A has an uppermost end below the interlayer dielectric 180 (e.g., the uppermost or lowermost surface thereof) and is an appropriate distance from the uppermost surface of the interlayer dielectric 180 to prevent penetration of tungsten (W) or the like into the air gap in a subsequent contact formation process. The upper region 1911 and the lower region 1913 are completed by this process. The second insulating layer 199 may comprise the same material as the first insulating layer 197, and there is no limitation thereto, and any silicon oxide (e.g., silicon dioxide) may be used.

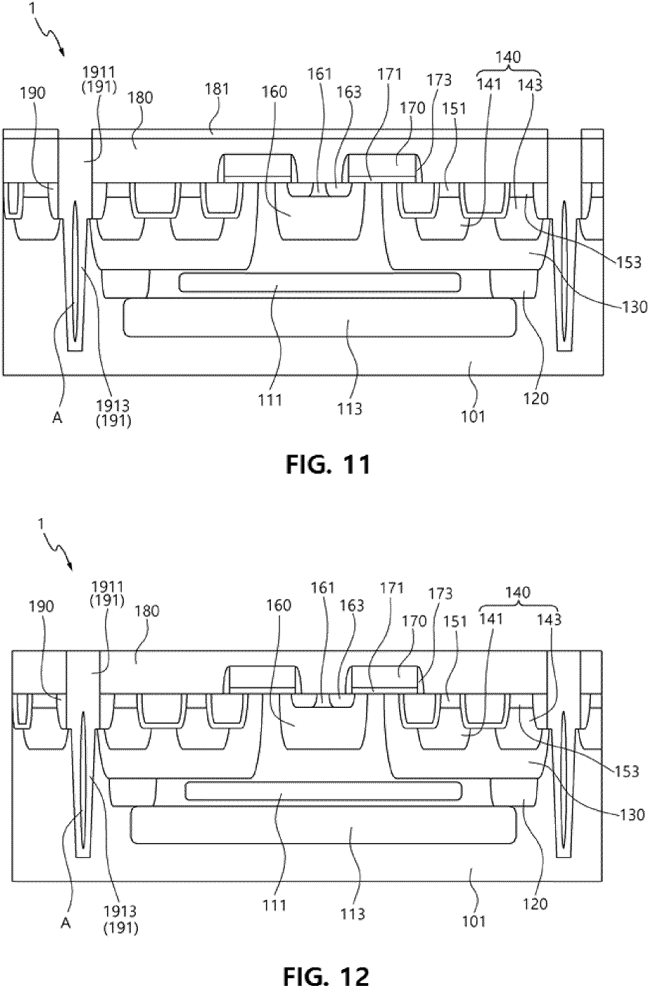

Thereafter, referring to FIG. 11, the excess second insulating layer 199 on the etch stop layer 181 is removed. That is, all of the second insulating layer 199 on the etch stop layer 181 is removed by polishing (e.g., CMP) using the etch stop layer 181 as a polishing stop.

Thereafter, referring to FIG. 12, the etch stop layer 181 is removed by selective etching, and a cleaning process may then be performed thereon.

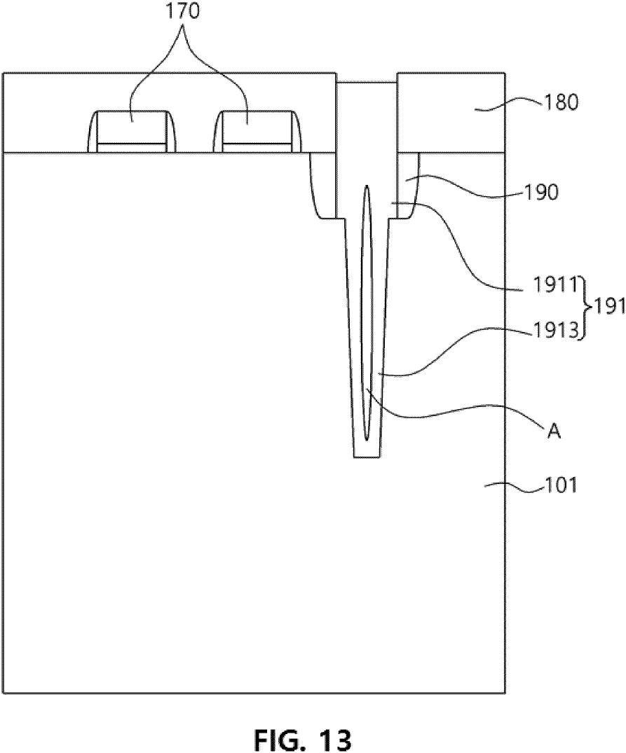

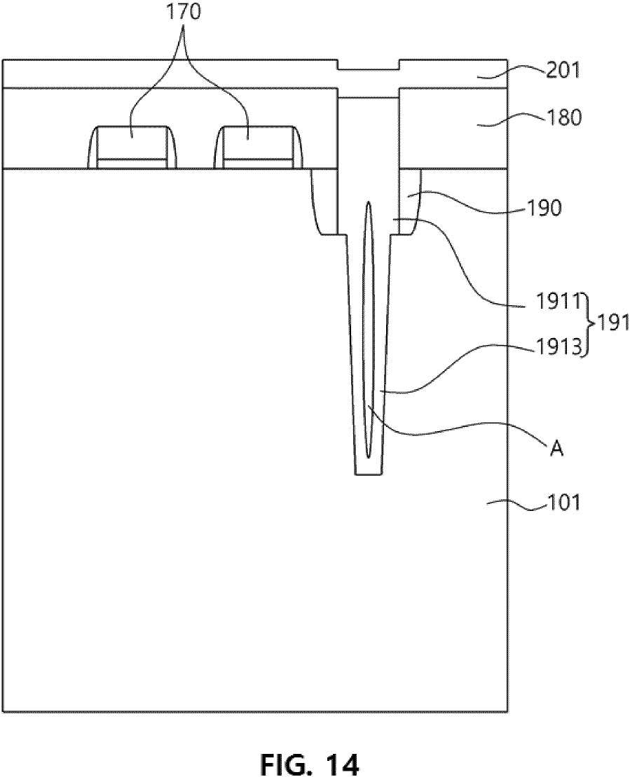

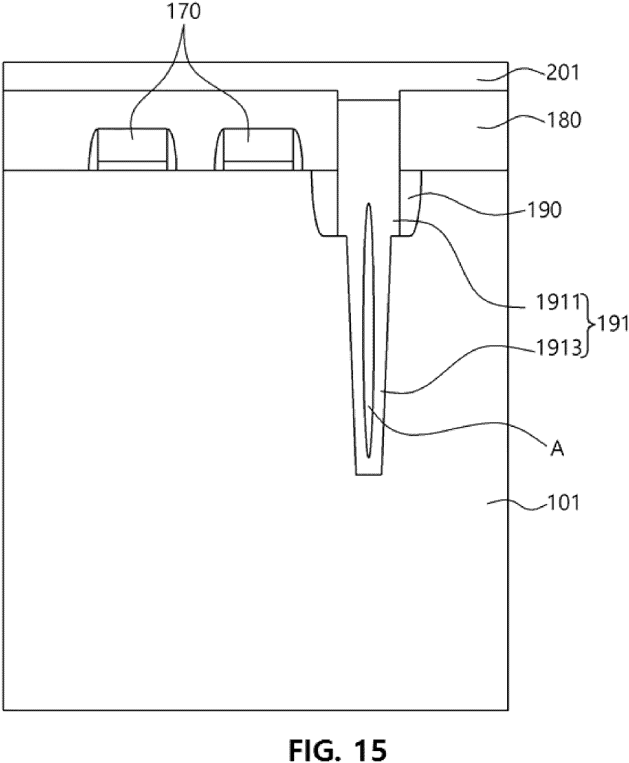

FIGS. 13 and 15 are cross-sectional views showing a process of removing a step height that may result at the boundary between the first isolation structure 191/1911 and the interlayer dielectric 180.

Referring to FIG. 13, the etch stop layer 181 is removed (e.g., by etching) while the upper region 1911 is exposed. In the process of etching the etch stop layer 181, the upper region 1911 may also be partially etched. That is, oxide loss may occur from the upper region 1911. Alternatively, the second isolation region 191 may have an uppermost surface that is substantially coplanar with the uppermost surface of the etch stop layer 181 (FIG. 11, but not explicitly shown therein), and the exposed surface of the second isolation region 191 may not be etched significantly during selective etching of the etch stop layer 181. Thereby, a step height between the second isolation region 191 and the interlayer dielectric 180 adjacent thereto may result, and in a subsequent contact formation process, a contact-forming material such as tungsten (W) may remain on the upper region 1911 that is partially recessed (or on the interlayer dielectric 180, which may have an uppermost surface below that of the second isolation region 191), resulting in deterioration of the characteristics of the second isolation region 191 (or of the device).

The process described below is for removing the step height, but it should be noted that such process is not an essential step of the present disclosure.

Referring to FIG. 14, a third insulating layer 201 is blanket-deposited on the interlayer dielectric 180 and on the second isolation region 191. The third insulating layer 201 may comprise a TEOS or other silicon oxide layer, but is not limited thereto. The third insulating layer 201 is a layer for removing the step height.

Thereafter, referring to FIG. 15, the third insulating layer 201 is planarized (e.g., by CMP). By planarizing the third insulating layer 201, it is possible to prevent the air gap A in the second isolation region 191 from being opened in subsequent processing and to remove the step height at the same time. The breakdown voltage characteristics of the device may also be improved by removing the step height.

The above detailed description is illustrative of the present disclosure. In addition, the above description shows and describes various embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiments describe various manners and/or states for implementing the technical idea of the present disclosure, and various changes for specific application fields and/or uses of the present disclosure are possible. Accordingly, the detailed description of the present disclosure is not intended to limit the present disclosure to the disclosed embodiments.

What is claimed is:

1. A semiconductor device, comprising:
a substrate;
a gate electrode on or over the substrate;
an interlayer dielectric covering the gate electrode and/or the substrate;
a first shallow trench isolation region in the substrate;
a second isolation region overlapping at least partially with the first shallow trench isolation region and penetrating into the substrate; and
an air gap in the second isolation region.

2. The semiconductor device of claim 1, wherein the second isolation region comprises:
an upper region overlapping with the first shallow trench isolation region; and
a lower region connected to the upper region, extending predetermined distance, and having a width smaller than that of the upper region.

3. The semiconductor device of claim 2, wherein the upper region has a smaller width than that of the first shallow trench isolation region.

4. The semiconductor device of claim 2, wherein the air gap is in the lower region.

5. The semiconductor device of claim 2, wherein the upper region is adjacent to the interlayer dielectric.

6. A semiconductor device, comprising:
a substrate;
a first buried layer having a second conductivity type in the substrate;
a deep well region directly or indirectly connected to the first buried layer;
a first well region in the deep well region;
a drain in the first well region and at a surface of the substrate;
a body region having a first conductivity type in the substrate;
a source in the body region and at the surface of the substrate;
a gate electrode on or over the substrate;
an interlayer dielectric covering the gate electrode and/or the substrate;
a first shallow trench isolation region in the substrate;
a second isolation region penetrating the first shallow trench isolation region and the substrate; and
an air gap in the second isolation region.

7. The semiconductor device of claim 6, further comprising:
a high-voltage well region having the second conductivity type, connected to the first buried layer and the deep well region; and
a second buried layer having the first conductivity type in the substrate.

8. The semiconductor device of claim 6, wherein the second isolation region comprises:
an upper region overlapping with the first shallow trench isolation region; and
a lower region connected to the upper region, extending a predetermined distance, and having a width smaller than that of the upper region.

9. The semiconductor device of claim 8, further comprising:
a dummy gate on the first shallow trench isolation region.

10. The semiconductor device of claim 9, wherein the upper region penetrates or passes through the dummy gate, and has sides in contact with and/or surrounded by the interlayer dielectric.

11. A method of manufacturing a semiconductor device, the method comprising:
forming a first shallow trench isolation region in a substrate;
forming a gate electrode on or over the substrate;
forming an interlayer dielectric covering the gate electrode and/or on the substrate;
forming an upper isolation region that overlaps the first shallow trench isolation region and penetrates the interlayer dielectric; and
forming a lower isolation region in the substrate, the lower isolation region having a smaller width than that of the upper isolation region.

12. The method of manufacturing a semiconductor device of claim 11, wherein the lower isolation region comprises:
an air gap therein.

13. The method of manufacturing a semiconductor device of claim 12, wherein forming the upper isolation region comprises:
forming a first trench by etching (i) the interlayer dielectric above the first shallow trench isolation region and (ii) the first shallow trench isolation region; and
depositing an insulating layer in the first trench, and
forming the lower isolation region comprises:
forming a second trench by etching the substrate under the first shallow trench isolation region; and
depositing the insulating layer in the second trench.

14. The method of manufacturing a semiconductor device of claim 13, wherein the insulating layer in the upper isolation region and in the lower isolation region are deposited practically simultaneously, and depositing the insulating layer comprises:
depositing a first insulating layer on the interlayer dielectric and on sidewalls of the first trench,
etching the first insulating layer to leave an insulating spacer or liner on sidewalls of the interlayer dielectric and the first trench; and
depositing a second insulating layer on the insulating spacer or liner in the first trench and the second trench.

15. The method of manufacturing a semiconductor device of claim 11, further comprising:
forming a dummy gate on the first shallow trench isolation region and the substrate,
wherein the upper isolation region penetrates or passes through the dummy gate.

16. A method of manufacturing a semiconductor device, the method comprising:
forming an STI region in a substrate;
forming a gate electrode on or over the substrate;
forming an interlayer dielectric covering the gate electrode and/or on the substrate;
forming an etch stop layer on the interlayer dielectric;
forming a first trench by etching the etch stop layer, the interlayer dielectric, and the STI region;
forming a second trench having a smaller width than the first trench by etching the substrate under the first trench to a predetermined depth;
filling the first trench and the second trench with a first insulating layer;
removing the first insulating layer on the etch stop layer; and
depositing a second insulating layer on the first insulating layer in the first trench and the second trench.

17. The method of manufacturing a semiconductor device of claim 16, further comprising:
removing the second insulating layer remaining on the etch stop layer; and
etching the etch stop layer.

18. The method of manufacturing a semiconductor device of claim 17, further comprising:
depositing a third insulating layer on the second insulating layer and the interlayer dielectric; and
planarizing the third insulating layer.

19. The method of manufacturing a semiconductor device of claim 16, wherein forming the first trench comprises:
forming a first photoresist pattern on the etch stop layer; and
sequentially etching the etch stop layer, the interlayer dielectric, and the first shallow trench isolation region.

20. The method of manufacturing a semiconductor device of claim 19, wherein forming the second trench comprises:
forming a second photoresist pattern on the etch stop layer and along sidewalls of the first trench; and
etching the substrate under the first trench.
